(19) United States
(12) Patent Application Publication
(10) Pub. No.: US 2024/0260404 A1
(43) Pub. Date: Aug. 1, 2024

(54) DISPLAY DEVICE

(71) Applicant: LG Display Co., Ltd., Seoul (KR)

(72) Inventor: KyungMo SON, Paju-si (KR)

(21) Appl. No.: 18/427,571

(22) Filed: Jan. 30, 2024

(30) Foreign Application Priority Data
Jan. 31, 2023 (KR) 10-2023-0012811

(51) Int. Cl. H10K 59/80; H10K 59/121; H10K 59/126; H10K 59/131; H10K 59/40; H10K 102/10

(52) U.S. Cl. CPC H10K 59/873; H10K 59/1213; H10K 59/126; H10K 59/131; H10K 59/40; H10K 59/80524; H10K 2102/103

(57) ABSTRACT

Provided is a display device. The display device includes a substrate including an active area and a non-active area. The display device includes a first light blocking layer on the substrate in the non-active area. The display device includes a first thin film transistor including a first active layer, a first gate electrode, a first source electrode, and a first drain electrode on the substrate in the non-active area. The display device includes a first metal layer between the first source electrode and the first light blocking layer, and the first drain electrode and the first light blocking layer in the non-active area. A distance between the first active layer and the first metal layer is shorter than a distance between the first metal layer and the first light blocking layer.

### CROSS-REFERENCE TO RELATED APPLICATIONS

This application claims the benefit of and priority to Korean Patent Application No. 10-2023-0012811 filed on Jan. 31, 2023, in the Republic of Korea, the entire contents of which are hereby expressly incorporated by reference into the present application.

### BACKGROUND

### Technical Field

The present disclosure relates to a display device.

### Description of the Related Art

Image display devices are a core technology of the information communication era and are developing to become thinner, lighter, and more portable, while having higher performance characteristics. Recently, demand for display devices that can be transformed into various shapes is increasing, and accordingly, studies on implementing display devices as foldable or rollable display devices is being actively conducted.

A light emitting display device is a self-luminous display device and can be manufactured to be light and thin since it does not require a separate light source, unlike a liquid crystal display device having a separate light source. In addition, the light emitting display device has advantages in terms of power consumption due to a low voltage driving, and is excellent in terms of a color implementation, a response speed, a viewing angle, and a contrast ratio (CR). Therefore, light emitting display devices are being studied as next-generation displays.

Such light emitting display devices require high reliability in terms of a response speed and power consumption.

### BRIEF SUMMARY

The present disclosure provides a display device configured to preventing defects caused by shifting a threshold voltage of a thin film transistor by forming a metal layer around the thin film transistor of a gate driver to trap hydrogen in an active layer.

A display device according to an exemplary embodiment of the present disclosure may include a substrate including an active area and a non-active area adjacent to the active area; a first light blocking layer on the substrate in the non-active area; a first thin film transistor including a first active layer, a first gate electrode, a first source electrode, and a first drain electrode on the substrate in the non-active area; and a first metal layer between the first source electrode and the first drain electrode and the first light blocking layer in the non-active area, wherein a distance between the first active layer and the first metal layer is shorter than a distance between the first metal layer and the first light blocking layer.

A display device according to an exemplary embodiment of the present disclosure may include a substrate including an active area and a non-active area adjacent to the active area; a first light blocking layer on the substrate in the non-active area; a first thin film transistor including a first active layer, a first gate electrode, a first source electrode, and a first drain electrode on the substrate in the non-active area; an encapsulation layer on the first thin film transistor; a touch electrode on the encapsulation layer; a dam portion spaced apart from the first thin film transistor; and a first metal layer between the dam portion and the first thin film transistor.

According to an exemplary embodiment of the present disclosure, a metal layer is formed around a thin film transistor of a gate driver to trap hydrogen in an active layer, so that it is possible to prevent defects caused by shifting a threshold voltage of the thin film transistor and allow for low-power driving.

It is to be understood that both the foregoing general description and the following detailed description of the present disclosure are exemplary and explanatory and are not intended to specify essential limitations recited in the claims. Therefore, the scope of the claims is not restricted by the foregoing general description and the following detailed description of the present disclosure.

### BRIEF DESCRIPTION OF THE SEVERAL VIEWS OF THE DRAWINGS

FIG. 1 is a block diagram of a display device according to an exemplary embodiment of the present disclosure.

FIG. 2 is a block diagram of a sub-pixel of the display device according to an exemplary embodiment of the present disclosure.

FIG. 3 is a circuit diagram of a sub-pixel of the display device according to an exemplary embodiment of the present disclosure.

FIG. 4 is a circuit diagram illustrating a stage circuit of the display device according to an exemplary embodiment of the present disclosure.

FIG. 5 is a view illustrating a display device according to an exemplary embodiment of the present disclosure.

FIG. 6 is a view illustrating a display device according to another embodiment of the present disclosure.

FIG. 7 is a view illustrating a display device according to still another embodiment of the present disclosure.

FIG. 8 is a view illustrating a display device according to still another embodiment of the present disclosure.

FIG. 9 is a view illustrating a display device according to still another embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

A shape, a size, a dimension (e.g., length, width, height, thickness, radius, diameter, area, etc.), a ratio, an angle, and a number of elements disclosed in the drawings for describing embodiments of the present disclosure are merely an example, and thus, the embodiments of the present disclosure are not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

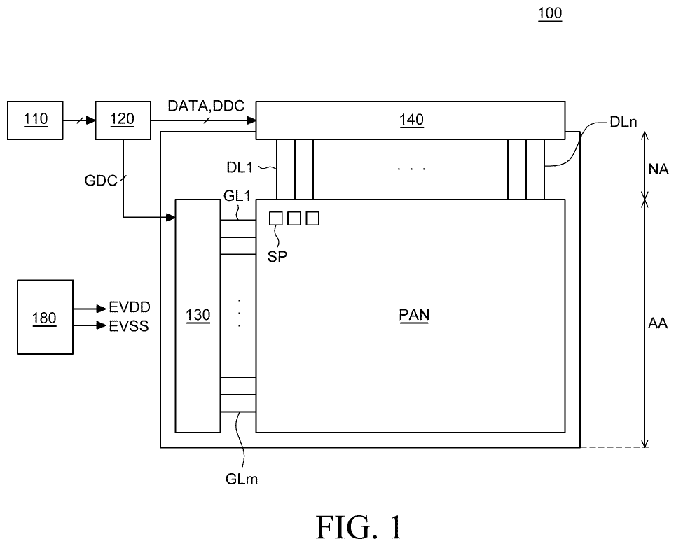

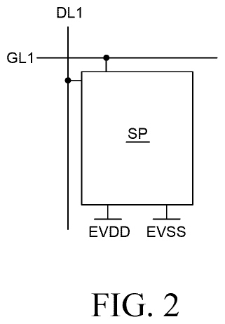

FIG. 1 is a block diagram of a display device according to an exemplary embodiment of the present disclosure. FIG. 2 is a block diagram of a sub-pixel of the display device according to an exemplary embodiment of the present disclosure.

As shown in FIGS. 1 and 2, the display device may include an image supply unit 110, a timing controller 120, a scan driver 130, a data driver 140, a display panel PAN, a power supply unit 180 and the like.

The image supply unit 110 (or host system) may output various driving signals in addition to image data signals supplied from the outside or image data signals stored in an internal memory. The image supply unit 110 may supply data signals and various driving signals to the timing controller 120.

The timing controller 120 may output a gate timing control signal GDC for controlling an operation timing of the scan driver 130, a data timing control signal DDC for controlling an operation timing of the data driver 140, and various synchronization signals (vertical synchronization signals Vsync and horizontal synchronization signals Hsync). The timing controller 120 may supply data signals DATA supplied from the image supply unit 110 to the data driver 140 together with the data timing control signal DDC. The timing controller 120 may be formed in a form of an integrated circuit (IC) and mounted on a printed circuit board, but is not limited thereto. The scan driver 130 may output a scan signal (or scan voltage) in response to the gate timing control signal GDC supplied from the timing controller 120. The scan driver 130 may supply a scan signal to sub-pixels included in the display panel PAN through gate lines GL1 to GLm. The scan driver 130 may be formed in the form of an IC or directly formed on the display panel PAN in a gate in panel (GIP) method, but is not limited thereto.

The data driver 140 samples and latches the data signals DATA in response to the data timing control signal DDC supplied from the timing controller 120, and based on a gamma reference voltage, may convert the data signal in a digital format into the data voltage in an analog format to output it. The data driver 140 may supply a data voltage to the sub-pixels included in the display panel 150 through data lines DL1 to DLn. The data driver 140 may be formed in the form of an IC and mounted on the display panel PAN or a printed circuit board, but is not limited thereto.

The power supply unit 180 may generate a first power of high potential and a second power of low potential based on an external input voltage supplied from the outside, and output them through a first power line EVDD and a second power line EVSS. The power supply unit 180 may generate and output voltages required to drive the scan driver 130 (e.g., gate voltages including a gate-high voltage and a gate-low voltage) or voltages required to drive the data driver 140 (drain voltages including a drain voltage and a half-drain voltage) or the like, as well as the first power and the second power.

The display panel PAN can display images in response to the driving signals including scan signals and data voltages, and the first power and the second power. The sub-pixels of the display panel PAN emit light directly. The display panel PAN can be manufactured based on a rigid or flexible substrate such as glass, silicon, or polyimide. In addition, the sub-pixels that emit light may be composed of sub-pixels including red, green, and blue sub-pixels, or sub-pixels including red, green, blue, and white sub-pixels.

One sub-pixel SP may be connected to a first gate line GL1, a first data line DL1, the first power line EVDD, and the second power line EVSS. The sub-pixel SP may include a pixel circuit including a switching transistor, a driving transistor, a capacitor, an organic light emitting diode OLED, and the like. The sub-pixel SP used in the display device directly emit light, so a circuit configuration is complex. In addition, there are various compensation circuits that compensate for deterioration of a light emitting diode that emits light, as well as a driving transistor that supplies driving current to the light emitting diode. Therefore, it should be referred that the sub-pixel SP is simply shown in the form of a block.

In the above description, it has been described as if the timing controller 120, the scan driver 130, the data driver 140, and the like are individual components. However, depending on an implementation method of the display device, one or more of the timing controller 120, the scan driver 130, and the data driver 140 may be integrated into one integrated circuit (IC).

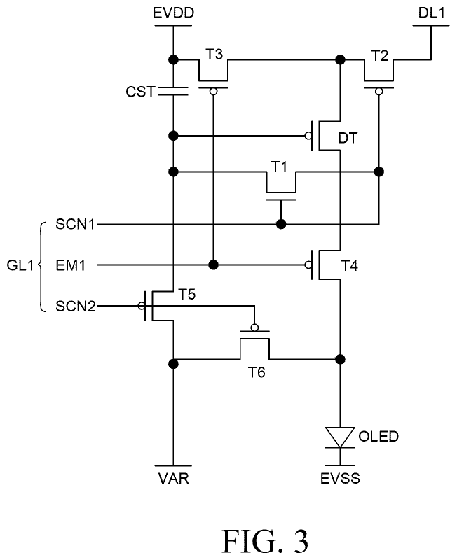

FIG. 3 is a circuit diagram of a sub-pixel of a display device according to an exemplary embodiment of the present disclosure.

As shown in FIG. 3, a sub-pixel that is applicable to the exemplary embodiment may include a first transistor T1, a second transistor T2, a third transistor T3, a fourth transistor T4, a fifth transistor T5, a sixth transistor T6, a capacitor CST, a driving transistor DT, and the organic light emitting diode OLED, but exemplary embodiments of the present disclosure are not limited thereto.

The sub-pixel that is applicable to the exemplary embodiment may be connected to a first gate line GL1 including a first scan line SCN1, a second scan line SCN2, and a first emission control line EM1. Here, as the second scan line SCN2, a scan line included in a front or rear sub-pixel rather than the sub-pixel that is currently shown, may be used.

The first and second transistors T1 and T2 may be turned on in response to a first scan signal transmitted through the first scan line SCN1, the fifth and sixth transistors T5 and T6 may be turned on in response to a second scan signal transmitted through the second scan line SCN2, and the third and fourth transistors T3 and T4 may be turned on in response to a first emission control signal transmitted through the first emission control line EM1.

The first scan signal may be applied during a sampling period and a data writing period for sampling a threshold voltage of the driving transistor DT and transmitting a data voltage of the first data line DL1 to a first node of the driving transistor DT. The second scan signal may be applied during an initialization period for transmitting a voltage of a voltage line VAR to a gate electrode of the driving transistor DT, a connection node of the capacitor CST, and an anode electrode of the organic light emitting diode OLED. The first emission control signal may be applied during an emission period for transmitting a high potential voltage of the first power line EVDD to the node of the driving transistor DT and transmitting a driving current generated from the driving transistor DT to the anode electrode of the organic light emitting diode OLED.

However, the sub-pixel described in FIG. 3 is only an example, and the present disclosure can be applicable to most structures in which effects of IR drops are caused on the display panel. In addition, the present disclosure describes, for convenience of explanation, an example in which the timing controller and the data driver are implemented as one integrated driving unit, but they can be separated as illustrated in FIG. 1.

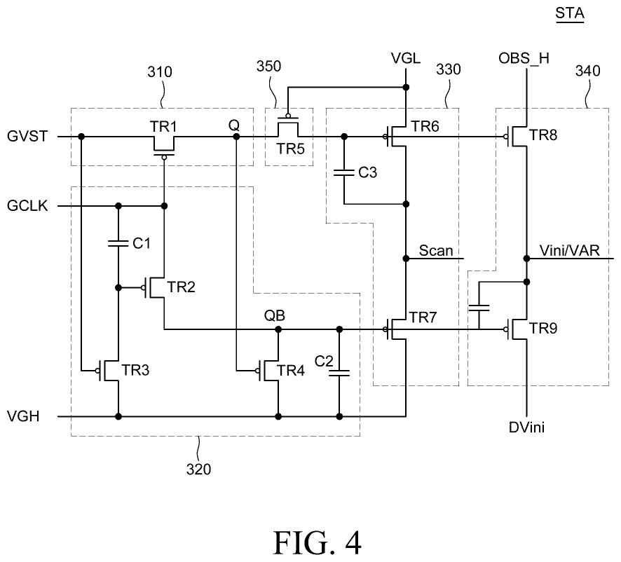

FIG. 4 is a circuit diagram illustrating a stage circuit of a gate driver of the display device according to an exemplary embodiment of the present disclosure.

As shown in FIG. 4, when a Q node is controlled by a gate-on voltage and a QB node is controlled by a gate-off voltage, a stage circuit STA outputs a first voltage VGH of a gate-on level as a scan signal Scan and a third voltage OBS_H, which is a blocking voltage, as an initialization voltage Vini/VAR. In addition, when the QB node is controlled by the gate-on voltage and the QB node is controlled by the gate-off voltage, the stage circuit STA outputs a second voltage VGL of a gate-off level as a scan signal Scan1, and outputs a fourth voltage DVini as the initialization voltage Vini/VAR. To this end, the stage circuit STA includes a first node controller 310, a second node controller 320, a first output buffer 330, a second output buffer 340, and a stabilization unit 350.

The first node controller 310 controls a Q node voltage. The first node controller 310 includes a first transistor TR1. The first transistor TR1 is turned on according to a gate clock signal GCLK and applies a gate start signal GVST (or an output signal of a previous stage circuit) to the Q node to thereby control the Q node voltage.

The second node controller 320 controls a QB node voltage in an opposite manner to the Q node. The second node controller 320 includes a first capacitor C1, a second transistor TR2, a third transistor TR3, a fourth transistor TR4, and a second capacitor C2.

The first capacitor C1 is connected between an input terminal of the gate clock signal GCLK and a gate electrode of the second transistor TR2 to stabilize a voltage of the gate electrode of the second transistor TR2.

The second transistor TR2 is turned on according to the voltage of the gate electrode and applies the gate clock signal GCLK to the QB node. The third transistor TR3 is turned on according to the gate start signal GVST (or the output signal of the previous stage circuit) and applies the first voltage VGH to the gate electrode of the second transistor TR2. Accordingly, the voltage of the gate electrode of the second transistor TR2 changes in synchronization with the gate clock signal GCLK while the gate start signal GVST is maintained at a gate-off level. In addition, the voltage of the gate electrode of the second transistor TR2 is controlled to the first voltage VGH while the gate start signal GVST is maintained at a gate-on level.

The fourth transistor TR4 is turned on according to a voltage of the Q node and applies the first voltage VGH to the QB node. When the Q node is at a low-level voltage, the fourth transistor TR4 may be turned on to apply the first voltage VGH to the QB node and charge the QB node to a high-level. When the Q node is at a high-level voltage, the fourth transistor TR4 may be turned off to discharge the QB node to a low-level.

The second capacitor C2 is connected between the QB node and the first voltage VGH to stabilize a voltage of the QB node.

The first output buffer 330 includes a sixth transistor TR6, which is a pull-down element, a seventh transistor TR7, which is a pull-up element, and a third capacitor C3. The sixth transistor TR6 is turned on when the Q node is controlled by the gate-on voltage and outputs the second voltage VGL to the scan line. The third capacitor C3 is connected between the Q node and a scan signal output node. When an output scan signal changes from the first voltage VGH to the second voltage VGL, the third capacitor C3 bootstraps the Q node by reflecting a change in voltage of the scan signal output node to the Q node.

The seventh transistor TR7 is turned on when the QB node is controlled by the gate-on voltage and outputs the first voltage VGH to the scan line.

The second output buffer 340 includes an eighth transistor TR8, which is a pull-down element, a ninth transistor TR9, which is a pull-up element, and a fourth capacitor C4. The eighth transistor TR8 is turned on when the Q node is controlled by the gate-on voltage and outputs the third voltage OBS_H, which is a blocking voltage, to an initialization voltage line.

The ninth transistor TR9 is turned on when the QB node is controlled by the gate-on voltage and outputs the fourth voltage DVini to the initialization voltage line. The fourth capacitor C4 is connected between the QB node and an initialization voltage output node. When an output initialization voltage changes from the fourth voltage DVini to the third voltage OBS_H, the fourth capacitor C4 bootstraps the QB node by reflecting a change in voltage of the initialization voltage output node to the QB node.

The stabilization unit 350 includes a fifth transistor TR5. The fifth transistor TR5 is connected between the Q node and a gate electrode of the sixth transistor TR6, and a gate electrode of the fifth transistor TR5 is connected to the second voltage VGL. A channel current in the fifth transistor TR5 becomes zero when a voltage in the gate electrode of the sixth transistor TR6 is bootstrapped. For example, the fifth transistor TR5 is turned on while a voltage in the gate electrode of the sixth transistor TR6 is bootstrapped and the fifth transistor TR5 blocks electrical connection between the Q node and the gate electrode of the sixth transistor TR6. The fifth transistor TR5 is turned on while the voltage in the gate electrode of the sixth transistor TR6 is not bootstrapped, thereby electrically connecting the Q node and the gate electrode of the sixth transistor TR6.

Since the Q node voltage is maintained by the fifth transistor TR5 when the voltage in the gate electrode of the sixth transistor TR6 is bootstrapped, overload is not caused in the first transistor TR1 and the fourth transistor TR4 that are connected to the Q node at a bootstrapping moment.

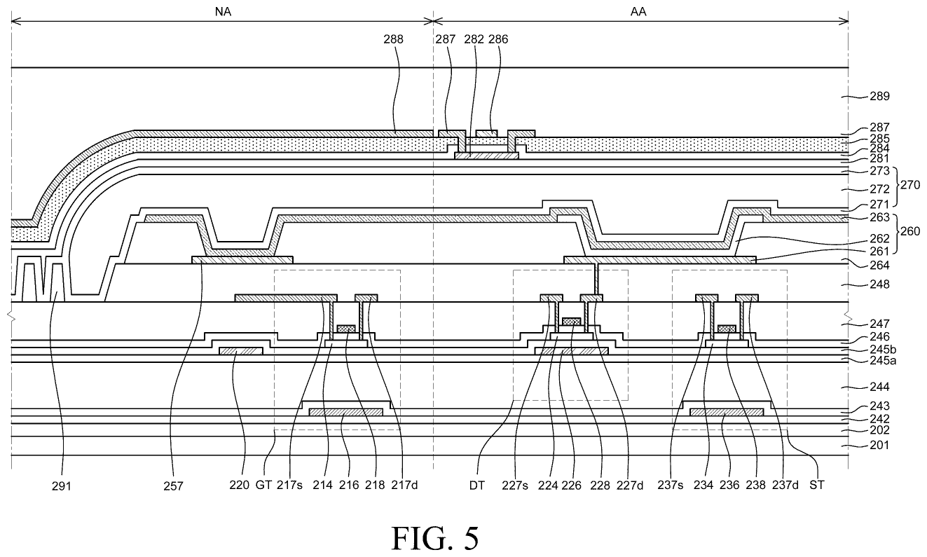

FIGS. 5 to 9 are views illustrating display devices according to exemplary embodiments of the present disclosure.

Referring to FIG. 5, a first thin film transistor GT, a driving transistor DT, and a switching thin film transistor ST including an oxide semiconductor are shown as examples.

The oxide semiconductor may be formed of an oxide of a metal such as zinc (Zn), indium (In), gallium (Ga), tin (Sn), or titanium (Ti), or a combination of a metal such as zinc (Zn), indium (In), gallium (Ga), tin (Sn) or titanium (Ti) and an oxide thereof, but exemplary embodiments of the present disclosure are not limited thereto. For example, examples of the oxide semiconductor may include zinc oxide (ZnO), zinc-tin oxide (ZTO), zinc-indium oxide (IZO), indium oxide (InO), titanium oxide (TiO), indium-gallium-zinc oxide (IGZO), indium-zinc-tin oxide (IZTO), and the like, but exemplary embodiments of the present disclosure are not limited thereto.

In the case of a thin film transistor using the oxide semiconductor as an active layer, it has been recognized that a threshold voltage of the thin film transistor is reduced due to the influence of hydrogen. Accordingly, the inventor of the present disclosure conducted various studies and experiments to implement a display device in which a threshold voltage of a thin film transistor does not decrease due to the influence of hydrogen. Through various studies and experiments, a new display device in which a conductive layer (e.g., a metal layer) capable of trapping hydrogen is configured around a thin film transistor, has invented.

The present disclosure suggests a thin film transistor having an oxide semiconductor as an active layer, which reduces the influence of hydrogen on the thin film transistor by forming a metal layer capable of trapping hydrogen around the gate driver. This will be explained below.

Referring to FIG. 5, the driving thin film transistor DT and the switching thin film transistor ST may be disposed in an active area AA. FIG. 5 illustrates only the driving thin film transistor DT and one switching thin film transistor ST, but this is only for convenience of explanation, and a plurality of switching thin film transistors or driving thin film transistors may be disposed in the actual active area AA. A gate driver may be disposed in a non-active area NA. The gate driver may be a driver including a gate-in-panel (GIP). For example, the gate driver may be a GIP, but exemplary embodiments of the present disclosure are not limited thereto. A plurality of first thin film transistors GT constituting the gate driver may be disposed in the non-active area NA.

A substrate 201 includes the active area AA and the non-active area NA. The substrate 201 is a component to support various components included in the display device 100 and may be formed of an insulating material. The substrate 201 may be composed of multi-layers in which an organic layer and an inorganic layer are alternately stacked, but exemplary embodiments of the present disclosure are not limited thereto. The substrate 201 may be formed by alternately stacking an organic layer such as glass or polyimide and an inorganic layer such as silicon oxide (SiO2), and may be formed of a material with flexibility. However, exemplary embodiments of the present disclosure are not limited thereto.

The active area AA may be an area where a plurality of sub-pixels SP are disposed to display an image. The plurality of sub-pixels SP are individual units that each emit light and include a red sub-pixel, a green sub-pixel, and a blue sub-pixel, or a white sub-pixel. However, the present disclosure is not limited thereto.

The non-active area NA may be an area where an image is not displayed. For example, the non-active area NA is an area where various lines, driver ICs and the like for driving the sub-pixels SP disposed in the active area AA are disposed. The non-active area NA may be located on a rear surface of the substrate 201, for example, on a surface of the substrate 201 without the sub-pixel SP, and is not limited to those illustrated in the drawings.

A lower buffer layer 202 may be formed on the substrate 201. The lower buffer layer 202 is intended to block moisture that may infiltrate from the outside and can be used by stacking a silicon oxide (SiO2) film in multiple layers.

A first gate insulating layer 242 may be formed on the lower buffer layer 202. The first gate insulating layer 242 may be formed of the same material as the lower buffer layer 202, but exemplary embodiments of the present disclosure are not limited thereto.

A first light blocking layer 216 may be formed on the first gate insulating layer 242 in the non-active area NA. For example, the first light blocking layer 216 may be disposed at a position overlapping with the first thin film transistor GT.

A third light blocking layer 236 may be formed on the first gate insulating layer 242 in the active area AA. For example, the third light blocking layer 236 may be disposed at a position overlapping with the switching thin film transistor ST.

The first light blocking layer 216 and the third light blocking layer 236 may be formed of a metal layer, but are not limited thereto. The first light blocking layer 216 and the third light blocking layer 236 may be formed to be greater than a first active layer 214 and a third active layer 234, respectively, so as to block external light entering the first active layer 214 and the third active layer 234, respectively. Accordingly, the first active layer 214 may overlap the first light blocking layer 216. For example, the first active layer 214 may overlap a portion of the first light blocking layer 216. In addition, the third active layer 234 may overlap the third light blocking layer 236. For example, the third active layer 234 may overlap a portion of the third light blocking layer 236. The first active layer 214 may completely overlap the first light blocking layer 216, and the third active layer 234 may completely overlap the third light blocking layer 236, but the exemplary embodiments of the present disclosure are not limited thereto.

The first light blocking layer 216 and the third light blocking layer 236 may be metal layers containing a titanium (Ti) material, but exemplary embodiments of the present disclosure are not limited thereto. For example, the first light blocking layer 216 and the third light blocking layer 236 may be a single layer of titanium, a double layer of molybdenum (Mo) and titanium (Ti), or an alloy of molybdenum (Mo) and titanium (Ti), but the present disclosure is not limited thereto.

A first interlayer insulating layer 243 may be formed on the first light blocking layer 216 and the third light blocking layer 236. The first interlayer insulating layer 243 includes at least one inorganic layer and may be formed of an inorganic material such as silicon oxide (SiO2), but the present disclosure is not limited thereto. For example, the first interlayer insulating layer 243 may be a first insulating layer, but exemplary embodiments of the present disclosure are not limited thereto.

A second interlayer insulating layer 244 may be formed on the first interlayer insulating layer 243. The second interlayer insulating layer 244 may be formed of an organic material such as polyimide or photo acrylate, but is not limited thereto. For example, the second interlayer insulating layer 244 may be a second insulating layer, but exemplary embodiments of the present disclosure are not limited thereto.

A first upper buffer layer 245a may be formed on the second interlayer insulating layer 244. The first upper buffer layer 245a may be formed of the same material as the lower buffer layer 202 or an organic material, but exemplary embodiments of the present disclosure are not limited thereto. For example, the first upper buffer layer 245a may be a first buffer layer, but exemplary embodiments of the present disclosure are not limited thereto.

A first metal layer 220 and a second light blocking layer 226 may be formed on the first upper buffer layer 245a. In the case of the first metal layer 220, it may be a metal layer formed in the non-active area NA and including a titanium (Ti) material with excellent hydrogen particle trapping ability, but the exemplary embodiments of the present disclosure are not limited thereto. Titanium (Ti), the material of the first metal layer 220, can prevent hydrogen particles from reaching the first active layer 214. In the case of hydrogen particles, they may have a negative effect on threshold voltage reliability of the first thin film transistor GT, and accordingly, the first metal layer 220 containing titanium (Ti) may trap hydrogen particles and prevent defects of the first thin film transistor GT. For example, the first metal layer 220 may be disposed in the gate driver. For example, the gate driver may be a gate-in-panel (GIP), but exemplary embodiments of the present disclosure are not limited thereto.

The first metal layer 220 may be formed of the same material as the first light blocking layer 216, the second light blocking layer 226, or the third light blocking layer 236, but exemplary embodiments of the present disclosure are not limited thereto. The first metal layer 220 may be formed in a floating state and may be electrically connected to other metal layers. For example, the second light blocking layer 226 may be in the same layer as the first metal layer 220. For example, the first light blocking layer 216 may be in the same layer as the third light blocking layer 236. For example, the first light blocking layer 216 may be in a layer different from that of the second light blocking layer 226. For example, the first light blocking layer 216 may be in a layer different from the third light blocking layer 236.

When the first metal layer 220 is adjacent to the first thin film transistor GT, it may interfere with characteristics of the first thin film transistor GT, so the first metal layer 220 can be formed to be spaced apart from the first active layer 214 so as not to interfere with the characteristics of the first thin film transistor GT.

The first metal layer 220 may overlap any one of a first source electrode 217s and a first drain electrode 217d.

A distance between the first metal layer 220 and the first active layer 214 may be shorter than a distance between the first metal layer 220 and the first light blocking layer 216.

When the distance between the first metal layer 220 and the first active layer 214 is shorter than the distance between the first metal layer 220 and the first light blocking layer 216, the influence of the first metal layer 220 on the first active layer 214 may be greater than the influence of the first light blocking layer 216 on the first active layer 214, in trapping hydrogen.

The second light blocking layer 226 is formed in the active area AA and may be formed of a metal layer containing titanium (Ti) or molybdenum (Mo), but exemplary embodiments of the present disclosure are not limited thereto. The second light blocking layer 226 may be formed to be larger than a second active layer 224 to block external light entering the second active layer 224. Accordingly, the second active layer 224 may overlap the second light blocking layer 226. For example, the second light blocking layer 226 may be formed to be larger than the second active layer 224 to block external light entering the second active layer 224. Accordingly, the second active layer 224 may overlap the second light blocking layer 226. For example, the second active layer 224 may overlap a portion of the second light blocking layer 226. For example, the second active layer 224 may completely overlap the second light blocking layer 226.

A second upper buffer layer 245b may be formed on the first metal layer 220 and the second light blocking layer 226. The second upper buffer layer 245b may be formed of the same material as the first upper buffer layer 245a, but exemplary embodiments of the present disclosure are not limited thereto. For example, the second upper buffer layer 245b may be a second buffer layer, but exemplary embodiments of the present disclosure are not limited thereto.

The first active layer 214, the second active layer 224, and the third active layer 234 may be formed on the second upper buffer layer 245b. The first active layer 214, the second active layer 224, and the third active layer 234 may each be formed of an oxide semiconductor or a polycrystalline silicon semiconductor. The first active layer 214 may be formed of an oxide semiconductor. For example, the oxide semiconductor may be formed of an oxide of a metal such as zinc (Zn), indium (In), gallium (Ga), tin (Sn), or titanium (Ti), or a combination of a metal such as zinc (Zn), indium (In), gallium (Ga), tin (Sn) or titanium (Ti) and an oxide thereof, but exemplary embodiments of the present disclosure are not limited thereto. For example, examples of the oxide semiconductor may include zinc-tin oxide (ZTO), zinc-indium oxide (ZInO), indium oxide (InO), titanium oxide (TiO), indium-gallium-zinc oxide (IGZO), indium-zinc-tin oxide (IZTO), and the like, but exemplary embodiments of the present disclosure are not limited thereto. For example, the first active layer 214, the second active layer 224, and the third active layer 234 may be a first semiconductor layer, a second semiconductor layer, and a third semiconductor layer, respectively, but exemplary embodiments of the present disclosure are not limited thereto. For example, the first active layer 214 and the second active layer 224 may be in the same layer.

The first active layer 214 and the third active layer 234 may be formed vertically above the first light blocking layer 216 and the third light blocking layer 236, respectively.

A second gate insulating layer 246 may be formed on the first active layer 214, the second active layer 224, and the third active layer 234. The second gate insulating layer 246 may be formed of the same material as the first gate insulating layer 242, but exemplary embodiments of the present disclosure are not limited thereto.

A first gate electrode 218, a second gate electrode 228, and a third gate electrode 238 may be formed on the second gate insulating layer 246. The first gate electrode 218 may be located in the non-active area NA and constitute the first thin film transistor GT, and the second gate electrode 228 and the third gate electrode 238 may be located in the active area AA and may constitute the driving thin film transistor DT and the switching thin film transistor ST, respectively.

According to an exemplary embodiment of the present disclosure, the driving thin film transistor DT may be disposed to be spaced apart from the first thin film transistor GT. For example, the driving thin film transistor DT may include the second active layer 224, the second gate electrode 228, a second source electrode 227s, and a second drain electrode 227d. For example, the driving thin film transistor DT may be a second thin film transistor, but exemplary embodiments of the present disclosure are not limited thereto.

According to an exemplary embodiment of the present disclosure, the switching thin film transistor ST may be disposed to be spaced apart from the first thin film transistor GT. For example, the switching thin film transistor ST may include the third active layer 234, the third gate electrode 238, a third source electrode 237s, and a third drain electrode 237d. For example, the switching thin film transistor ST may be a third thin film transistor, but exemplary embodiments of the present disclosure are not limited thereto.

The first gate electrode 218, the second gate electrode 228, and the third gate electrode 238 may be formed of a metal material. The first gate electrode 218, the second gate electrode 228, and the third gate electrode 238 may be a single layer or multiple layers formed of any one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first gate electrode 218, the second gate electrode 228, and the third gate electrode 238 may be formed on the first active layer 214, the second active layer 224, and the third active layer 234, respectively. For example, the first gate electrode 218, the second gate electrode 228, and the third gate electrode 238 may be formed to partially overlap with the first active layer 214, the second active layer 224, and the third active layer 234, respectively. The first gate electrode 218 and the second gate electrode 228 may be formed in the same layer. The first gate electrode 218, the second gate electrode 228, and the third gate electrode 238 may be formed in the same layer.

A third interlayer insulating layer 247 may be formed on the first gate electrode 218, the second gate electrode 228, and the third gate electrode 238. The third interlayer insulating layer 247 may be formed of the same material as the second interlayer insulating layer 244, but the exemplary embodiments of the present disclosure are not limited thereto.

On the third interlayer insulating layer 247, the first source electrode and the first drain electrode 217s and 217d, the second source electrode and the second drain electrode 227s and 227d, and the third source electrode and the third drain electrode 237s and 237d may be formed. The first source electrode and the first drain electrode 217s and 217d may be located in the non-active area NA, the second source electrode and the second drain electrode 227s and 227d, and the third source electrode and the third drain electrode 237s and 237d may be located in the active area AA.

The first source electrode and the first drain electrode 217s and 217d, the second source electrode and the second drain electrode 227s and 227d, and the third source electrode and the third drain electrode 237s and 237d may be electrically connected to the first active layer 214, the second active layer 224, and the third active layer 234, respectively, through contact holes of the third interlayer insulating layer 247.

A planarization layer 248 may be formed on the third interlayer insulating layer 247.

The planarization layer 248 may be formed to cover the first source electrode and the first drain electrode 217s and 217d, the second source electrode and the second drain electrode 227s and 227d, and the third source electrode and the third drain electrode 237s and 237d. The planarization layer 248 may be formed of an organic material such as photo acrylate, or may be composed of a plurality of layers including an inorganic layer and an organic layer, but the exemplary embodiments of the present disclosure are not limited thereto. For example, the planarization layer 248 may be a protective layer, but exemplary embodiments of the present disclosure are not limited thereto. The planarization layer 248 may be formed of a material such as acryl resin, epoxy resin, phenolic resin, polyamide resin, polyimide resin or the like, but exemplary embodiments of the present disclosure are not limited thereto.

An anode electrode 261 may be formed on the planarization layer 248 in the active area AA. The anode electrode 261 may be electrically connected to the second source and drain electrodes 227s and 227d through contact holes in the planarization layer 248.

A light emitting layer 262 may be formed on the anode electrode 261 of the active area AA that is provided by a bank 264.

After a plurality of thin film transistors are formed in the active area AA, a light emitting element unit 260 and an encapsulation unit 270 may be further formed on the substrate 201.

The driving thin film transistor DT may be electrically connected to the anode electrode 261 of the light emitting element unit 260 through a contact hole in the planarization layer 248.

The anode electrode 261 may be formed of a metal material having high reflectance such as a stacked structure (Ti/Al/Ti) of aluminum (Al) and titanium (Ti), a stacked structure (ITO/Al/ITO) of aluminum (Al) and ITO, an APC alloy, or a stacked structure (ITO/APC/ITO) of an APC alloy and ITO. For example, the APC alloy is an alloy of silver (Ag), palladium (Pd), and copper (Cu). For another example, the anode electrode 261 may be formed of a single layer or multiple layers formed of metals such as calcium (Ca), barium (Ba), magnesium (Mg), aluminum (Al), silver (Ag), or alloys thereof. However, exemplary embodiments of the present disclosure are not limited thereto.

A connection electrode 257 that electrically connects a common voltage line VSS and a cathode electrode 263 may be further provided in the non-active area NA.

The bank 264 may be formed on the planarization layer 248. The bank 264 is a type of partition wall that divides the respective sub-pixels and prevents light of a specific color output from the sub-pixels adjacent from being mixed and output.

The light emitting layer 262 may be formed on a surface of the anode electrode 261 and on a portion of an inclined surface of the bank 264. The light emitting layer 262 is formed in each sub-pixel and the light emitting layers 262 may include an R-light emitting layer that emits red light, a G-light emitting layer that emits green light, and a B-light emitting layer that emits blue light. The light emitting layer 262 may further include a W-light emitting layer that emits white light. For another example, the light emitting layer 262 may be an organic light emitting layer, an inorganic light emitting layer, a quantum dot light emitting layer, a micro-light emitting diode, or a micro-mini light emitting diode, but exemplary embodiments of the present disclosure are not limited thereto.

The light emitting element unit 260 may include not only the light emitting layer, but also an electron injection layer and a hole injection layer, which respectively inject electrons and holes into the light emitting layer, and an electron transport layer and a hole transport layer, which respectively transport the injected electrons and holes to the light emitting layer 262. However, exemplary embodiments of the present disclosure are not limited thereto.

The cathode electrode 263 may be formed on the light emitting layer 262. The cathode electrode 263 may be formed of a transparent conductive material such as indium tin oxide (ITO) or indium zinc oxide (IZO), or a metal that transmits visible light, but is not limited thereto. For another example, a capping layer may be further disposed on the cathode electrode 263.

The cathode electrode 263 and the connection electrode 257 may be directly connected in the non-active area NA. A connection portion of the cathode electrode 263 and the connection electrode 257 may partially overlap the first metal layer 220.

The encapsulation unit 270 may be formed on the cathode electrode 263 throughout the active area AA and the non-active area NA. The encapsulation unit 270 may be composed of a single layer including an inorganic layer or a combination of an inorganic layer and an organic layer, but exemplary embodiments of the present disclosure are not limited thereto. In the present disclosure, a first inorganic layer 271, an organic encapsulation layer 272, and a second inorganic encapsulation layer 273 may be configured, but the present disclosure is not limited thereto. The inorganic layer may be formed of an inorganic material such as silicon nitride (SiNx) and a silicon compound (SiX), but is not limited thereto. The organic layer may be formed of an organic material such as polyethylene terephthalate, polyethylene naphthalate, polycarbonate, polyimide, polyethylene sulfonate, polyoxymethylene, and polyarylate, or a mixture thereof, but is not limited thereto.

A touch buffer layer 281 may be formed on the second inorganic encapsulation layer 273 of the encapsulation unit 270. The touch buffer layer 281 may be formed of an inorganic layer or an organic layer, but exemplary embodiments of the present disclosure are not limited thereto. When the touch buffer layer 281 is formed of an inorganic layer, it may be formed of silicon oxide (SiOx), silicon nitride (SiNx), or a multilayer thereof, but exemplary embodiments of the present disclosure are not limited thereto. For example, the buffer layer 281 may be a touch buffer layer, but exemplary embodiments of the present disclosure are not limited thereto.

A first bridge electrode 282 may be formed on the buffer layer 281. The first bridge electrode 282 may be formed as a single layer or multiple layers formed of any one of molybdenum (Mo), aluminum (Al), chromium (Cr), gold (Au), titanium (Ti), nickel (Ni), neodymium (Nd), and copper (Cu), or alloys thereof, but exemplary embodiments of the present disclosure are not limited thereto.

An inorganic layer 284 may be formed on the first bridge electrode 282. The inorganic layer 284 may be formed of silicon oxide (SiOx), silicon nitride (SiNx), or a multilayer thereof, but exemplary embodiments of the present disclosure are not limited thereto.

An organic layer 285 may be formed on the inorganic layer 284. An order of the inorganic layer 284 and the organic layer 285 may be changed, but for convenience, they will be described in the order of the inorganic layer 284 and the organic layer 285. Since a contact hole is formed in the organic layer 285, it may include a photosensitive material. The organic layer 285 may be formed of photo acrylate including a photosensitive material, but exemplary embodiments of the present disclosure are not limited thereto.

A touch electrode 287 and a second bridge electrode 286 are formed on the organic layer 285. The touch electrode 287 may be connected to the first bridge electrode 282 through a contact hole penetrating the inorganic layer 284. The touch electrode 287 may be disposed to overlap the bank 264 to prevent a reduction in an opening area, but exemplary embodiments of the present disclosure are not limited thereto.

The touch electrode 287 may be formed on the organic layer 285 throughout the active area AA and the non-active area NA.

A protective layer 289 may be formed on the touch electrode 287. The protective layer 289 may protect the display panel PAN from external air or moisture. The protective layer 289 may be formed of an organic insulating material, a circularly polarizing plate, or a film formed of an epoxy or acrylic material, but exemplary embodiments of the present disclosure are not limited thereto.

A plurality of dam portions 291 may be formed around the first thin film transistor GT in the non-active area NA. The plurality of dam portions 291 may be formed on the third interlayer insulating layer 247. Accordingly, lowermost portions of the plurality of dam portions 291 may be formed on the third interlayer insulating layer 247.

The first metal layer 220 may be formed between the plurality of dam portions 291 and the first thin film transistor GT. As the first metal layer 220 is positioned between the plurality of dam portions 291 and the first thin film transistor G, defects of the light emitting element unit that occur when the first thin film transistor GT is close to the first metal layer 220 is prevented, and the first metal layer 220 traps hydrogen that affects the first thin film transistor GT, so that reliability of the light emitting element unit can be increased.

The plurality of dam portions 291 may be formed of the same material as the planarization layer 248 or the bank 264.

The second inorganic encapsulation layer 273 and the touch buffer layer 281 may also be formed on the plurality of dam portions 291 in the non-active area NA.

Hereinafter, various structures of the first thin film transistor GT and the first metal layer 220 in the non-active area NA will be described.

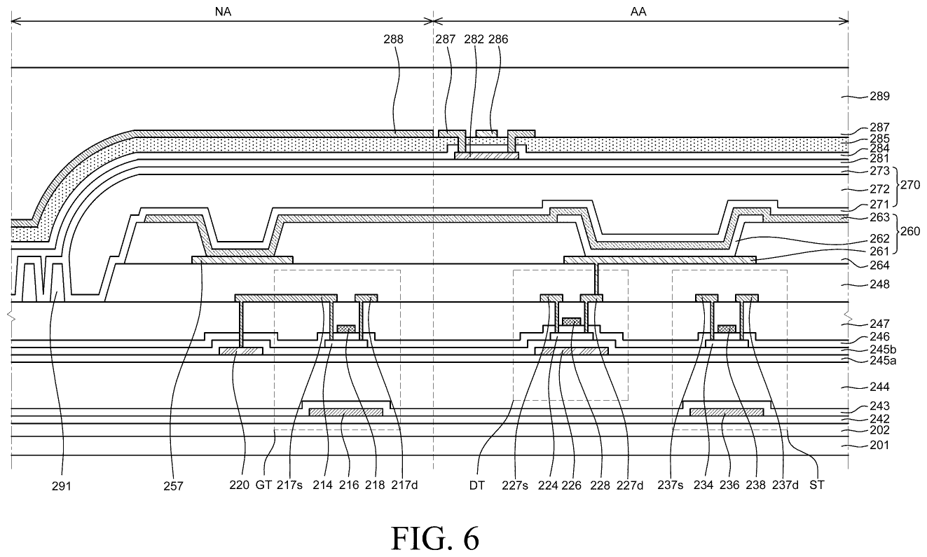

As shown in FIG. 6, the first thin film transistor GT may be electrically connected to the first metal layer 220 in the non-active area NA. At least one of the first source electrode and the first drain electrode 217s and 217d of the first thin film transistor GT may be connected to the first metal layer 220 through contact holes penetrating the second upper buffer layer 245b, the second gate insulating layer 246, and the third interlayer insulating layer 247. The first metal layer 220 is electrically connected to the first source electrode and the first drain electrodes 217s and 217d and can be prevented from floating.

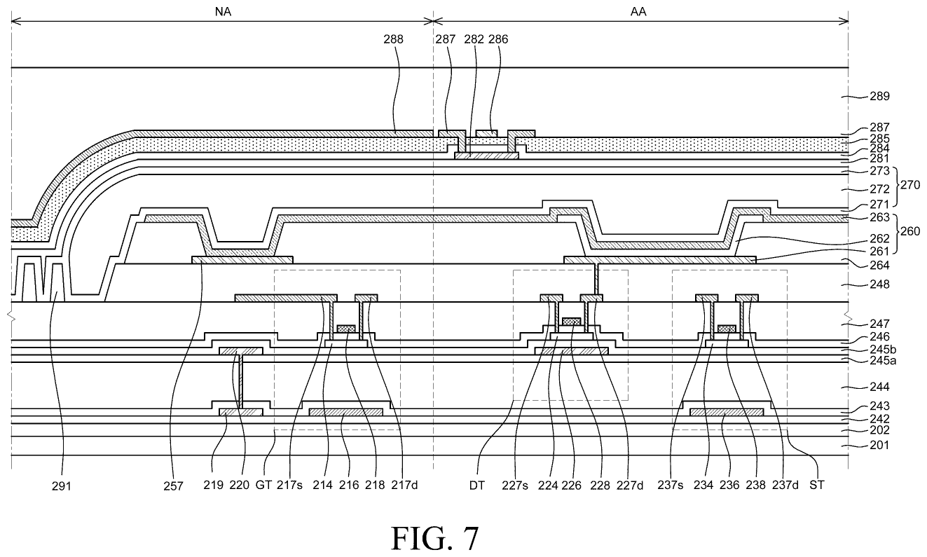

As shown in FIG. 7, a second metal layer 219 may be formed on the first gate insulating layer 242 in the non-active area NA.

For example, the second metal layer 219 may be below the first metal layer 220. The first metal layer 220 may be electrically connected to the second metal layer 219 in the non-active area NA. The second metal layer 219 may be located in the same layer as the first light blocking layer 216. Even if the first metal layer 220 is not electrically connected to the first thin film transistor GT, a metal with excellent hydrogen trapping ability is used, so it is possible to reduce the influence of hydrogen on the first thin film transistor GT and increase reliability of the light emitting element unit.

The first metal layer 220 is electrically connected to the second metal layer 219 and can be prevented from floating.

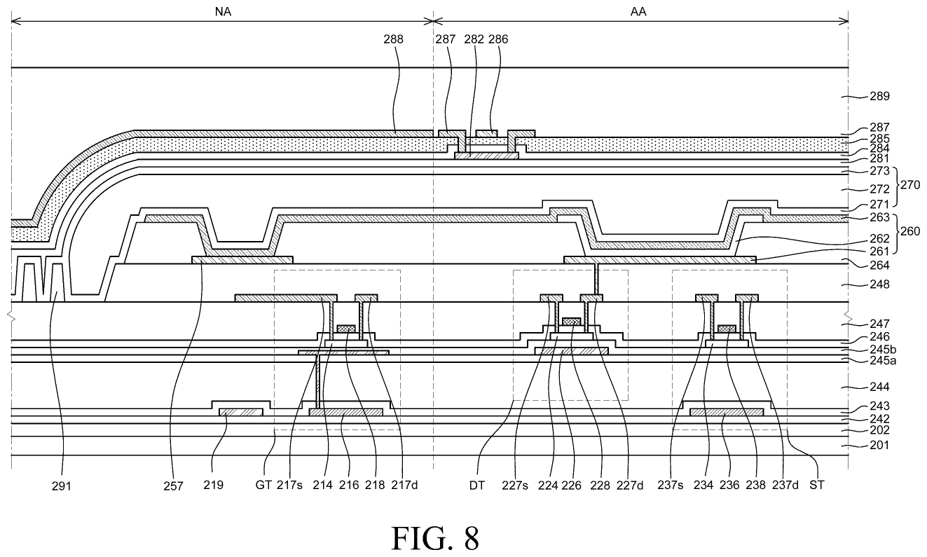

As shown in FIG. 8, in the non-active area NA, the first metal layer 220 may be located in an area in which it is electrically connected and overlaps with the first light blocking layer 216. The distance between the first metal layer 220 and the first active layer 214 may be shorter than the distance between the first metal layer 220 and the first light blocking layer 216.

When the distance between the first metal layer 220 and the first active layer 214 located in the non-active area NA is shorter than the distance between the first metal layer 220 and the first light blocking layer 216, since hydrogen that affects the first active layer 214 can be trapped at a location which is closer to the first metal layer 220 than the first light blocking layer 216, reliability of the light emitting element unit or the display device can be improved.

The first metal layer 220 is electrically connected to the first light blocking layer 216 and can be prevented from floating.

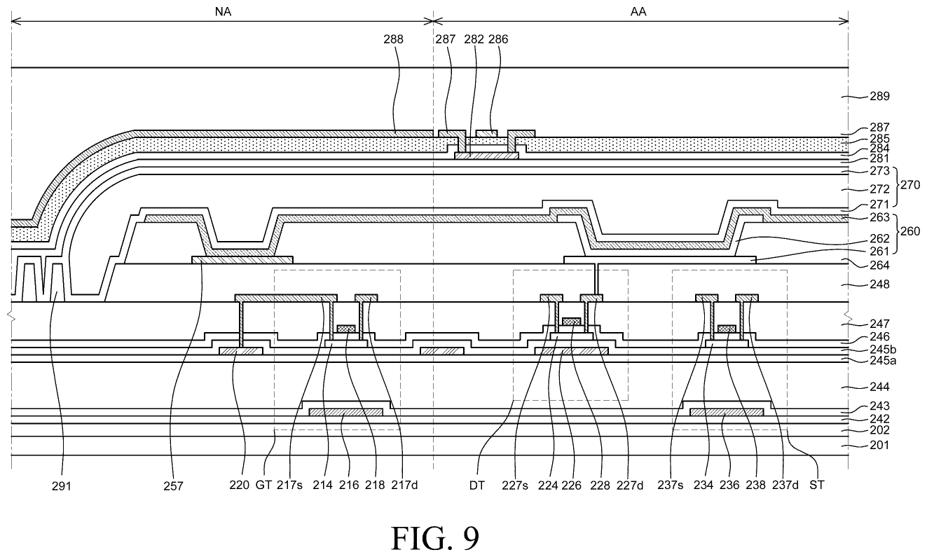

As shown in FIG. 9, the first metal layer 220 may surround the first thin film transistor GT in a ring shape in the non-active area NA. That is, when seen from a plan view, the first metal layer 220 may laterally surround the first thin film transistor GT in a ring shape in the non-active area NA. The first metal layer 220 may be electrically connected to the first source electrode and the first drain electrode 217s and 217d of the first thin film transistor GT.

The first metal layer 220 is electrically connected to the first source electrode and the first drain electrodes 217s and 217d and can be prevented from floating.

The exemplary embodiments of the present disclosure can also be described as follows:

According to an aspect of the present disclosure, there is provided a display device. The display device comprises a substrate including an active area and a non-active area adjacent to the active area; a first light blocking layer on the substrate in the non-active area; a first thin film transistor including a first active layer, a first gate electrode, a first source electrode, and a first drain electrode on the substrate in the non-active area; and a first metal layer between the first source electrode and the first light blocking layer, and the first drain electrode and the first light blocking layer in the non-active area. A distance between the first active layer and the first metal layer is shorter than a distance between the first metal layer and the first light blocking layer.

The first active layer may include an oxide semiconductor.

The first metal layer may be electrically connected to the first thin film transistor.

In some embodiments, the first metal layer may at least partially surround the first thin film transistor. In some embodiments, the first metal layer may fully surround in a horizontal plane, namely laterally, the first thin film transistor. In some embodiments, the first metal layer may surround the first thin film transistor from a plan view.

The first light blocking layer and the first metal layer may be electrically connected.

A gate driver may be disposed in the non-active area.

The first active layer may overlap the first light blocking layer.

Any one of the first source electrode and the first drain electrode may overlap the first metal layer.

The display device may further comprise a second thin film transistor disposed in the active area to be spaced apart from the first thin film transistor, and including a second gate electrode, a second active layer, a second source electrode, and a second drain electrode.

The first active layer and the second active layer may be in the same layer.

The first gate electrode and the second gate electrode may be in the same layer.

The display device may further comprise a second light blocking layer below the second active layer.

The second light blocking layer and the first metal layer may be in the same layer.

The display device may further comprise a second metal layer below the first metal layer.

The first metal layer and the second metal layer may be electrically connected.

The display device may further comprise a connection electrode on the first active layer in the non-active area.

The display device may further comprise a cathode electrode electrically connected to the connection electrode in the non-active area.

According to an aspect of the present disclosure, there is provided a display device. The display device comprises a substrate including an active area and a non-active area adjacent to; a first light blocking layer on the substrate in the non-active area; a first thin film transistor including a first active layer, a first gate electrode, a first source electrode, and a first drain electrode on the substrate in the non-active area; an encapsulation layer on the first thin film transistor; a touch electrode on the encapsulation layer; a dam portion spaced apart from the first thin film transistor; and a first metal layer between the dam portion and the first thin film transistor.

The first active layer may include an oxide semiconductor.

The first metal layer may be electrically connected to at least one of the first source electrode and the first drain electrode.

The first light blocking layer and the first metal layer may be electrically connected.

The non-active area may include a gate driver, and the first thin film transistor may be disposed in the gate driver.

The display device may further comprise a connection electrode on the first active layer in the non-active area.

The display device may further comprise a cathode electrode that meets the connection electrode in the non-active area. For example, as shown in FIG. 7, the cathode electrode comes into contact with the connection electrode in the non-active area.

Display devices according to exemplary embodiments of the present disclosure can be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic notebooks, e-books, portable multimedia players (PMPs), personal digital assistants (PDAs), MP3 players, mobile medical devices, desktop PCs, laptop PCs, netbook computers, workstations, navigations, vehicle navigations, vehicle display devices, vehicle devices, theater devices, theater display devices, televisions, wallpaper devices, signage devices, game devices, laptops, monitors, cameras, camcorders, and home appliances.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including an active area and a non-active area adjacent to the active area;
a first light blocking layer on the substrate in the non-active area;
a first thin film transistor including a first active layer, a first gate electrode, a first source electrode, and a first drain electrode on the substrate in the non-active area; and
a first conductive layer between the first source electrode and the first light blocking layer, and the first drain electrode and the first light blocking layer in the non-active area,
wherein a distance between the first active layer and the first conductive layer is shorter than a distance between the first conductive layer and the first light blocking layer.

2. The display device of claim 1, wherein the first conductive layer includes a first metal layer.

3. The display device of claim 2, wherein the first active layer includes an oxide semiconductor.

4. The display device of claim 2, wherein the first metal layer is electrically connected to the first thin film transistor.

5. The display device of claim 2, wherein the first metal layer at least partially surrounds the first thin film transistor.

6. The display device of claim 2, wherein the first metal layer laterally surrounds the first thin film transistor from a plan view.

7. The display device of claim 2, wherein the first light blocking layer and the first metal layer are electrically connected.

8. The display device of claim 2, further comprising a gate driver disposed in the non-active area.

9. The display device of claim 2, wherein the first active layer overlaps the first light blocking layer.

10. The display device of claim 2, wherein the first active layer overlaps the first light blocking layer from a plan view.

11. The display device of claim 2, wherein any one of the first source electrode and the first drain electrode overlaps the first metal layer.

12. The display device of claim 2, further comprising:
a second thin film transistor disposed in the active area to be spaced apart from the first thin film transistor, and including a second gate electrode, a second active layer, a second source electrode, and a second drain electrode.

13. The display device of claim 12, wherein the first active layer and the second active layer are in the same layer.

14. The display device of claim 12, wherein the first gate electrode and the second gate electrode are in the same layer.

15. The display device of claim 12, further comprising:
a second light blocking layer below the second active layer.

16. The display device of claim 15, wherein the second light blocking layer and the first metal layer are in the same layer.

17. The display device of claim 12, further comprising:
a second metal layer below the first metal layer.

18. The display device of claim 17, wherein the first metal layer and the second metal layer are electrically connected.

19. The display device of claim 2, further comprising:
a connection electrode on the first active layer in the non-active area.

20. The display device of claim 19, further comprising:
a cathode electrode electrically connected to the connection electrode in the non-active area.

21. A display device, comprising:
a substrate including an active area and a non-active area adjacent to the active area;
a first light blocking layer on the substrate in the non-active area;
a first thin film transistor including a first active layer, a first gate electrode, a first source electrode, and a first drain electrode on the substrate in the non-active area;
an encapsulation layer on the first thin film transistor;
a touch electrode on the encapsulation layer;
a dam portion spaced apart from the first thin film transistor; and
a first metal layer between the dam portion and the first thin film transistor.

22. The display device of claim 21, wherein the first active layer includes an oxide semiconductor.

23. The display device of claim 21, wherein the first metal layer is electrically connected to at least one of the first source electrode and the first drain electrode.

24. The display device of claim 21, wherein the first light blocking layer and the first metal layer are electrically connected.

25. The display device of claim 21, further comprising a gate driver disposed in the non-active area,
wherein the first thin film transistor is included in the gate driver.

26. The display device of claim 21, further comprising:
a connection electrode on the first active layer in the non-active area.

27. The display device of claim 23, further comprising:
a cathode electrode that contacts the connection electrode in the non-active area.
